(19) United States
(12) Patent Application Publication
(10) Pub. No.: US 2007/0102805 A1
(43) Pub. Date: May 10, 2007

(54) CHIP TYPE ELECTRIC DEVICE AND METHOD, AND DISPLAY DEVICE INCLUDING THE SAME

(75) Inventors: Hyung Guel KIM, Yongin-si, Gyeonggi-do (KR); Kun Bin LEE, Suwon-si, Gyeonggi-do (KR); Dong Hwan KIM, Suwon-si, Gyeonggi-do (KR); Ahn Ho JEE, Hwaseong-si, Gyeonggi-do (KR); Hyeong Cheol AHN, Suwon-si, Gyeonggi-do (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD, Suwon-si (KR)

(21) Appl. No.: 11/553,519

(22) Filed: Oct. 27, 2006

(30) Foreign Application Priority Data
Nov. 4, 2005 (KR) 10-2005-0105281

(51) Int. Cl. H01L 23/04

(52) U.S. Cl. 257/698

(57) ABSTRACT

A chip type electric device and a display device including the same is capable of preventing a bonding defect caused by a deviation in height between external electrodes. The chip type electric device includes a body in which a plurality of dielectric layers is stacked, a contact hole penetrating at least one of the plurality of dielectric layers, pairs of connection electrodes buried within the contact hole, and pairs of external electrodes connected to the pairs of connection electrodes and formed on a back surface of the body.

This application claims priority to Korean Patent Application No. 2005-105281, filed on Nov. 4, 2005 and all the benefits accruing therefrom under 35 U.S.C. §119, and the contents of which in its entirety are herein incorporated by reference.

### BACKGROUND OF THE INVENTION

1. Field of the Invention

The present invention relates to a chip type electric device and a liquid crystal display (“LCD”) device including the same, and more particularly, to a chip type electric device capable of preventing a bonding defect caused by a deviation in height between external electrodes, and a display device including the same.

2. Description of the Related Art

As there have been growing demands for small, lightweight electronic equipment, chip type electric devices are widely used to increase the wiring density of a circuit board. Examples of the chip type electric devices include a multilayer ceramic capacitor (“MLCC”), a chip resistor and a chip inductor.

The MLCC is a chip type capacitor of which a dielectric layer and an internal electrode are multilayered with a small, thin film. The chip resistor is a small, thin resistor for a surface package. The chip inductor is a surface package type inductor used to remove the noise of electronic equipment.

A conventional chip type electric device is mounted on a printed circuit board (“PCB”) or a flexible printed circuit (“FPC”) board by a soldering process. However, since there is a tendency to remove the PCB or FPC in order to reduce costs and make an LCD thin, a chip type electric device capable of being mounted on an LCD panel has been in demand.

Referring to FIG. 1, a conventional chip type electric device 2 mounted on the PCB or FPC includes a body 4 including a stacked plurality of dielectric layers, and a plurality of pairs of external electrodes 6 and 8. Each pair of external electrodes 6 and 8 face each other with the body 4 disposed therebetween.

The external electrode pairs 6 and 8 are formed at opposing sides of the body 4 to be connected to internal electrodes formed within the body 4 and formed at the bottom of the body 4 to be connected to conductive pads of the LCD panel. When the external electrode pairs 6 and 8 are formed by a photolithography process including an etching process, they are formed at the side of the body 4 and then formed at the bottom of the body 4. Therefore, a photolithography process and an etching process are needed at least twice, respectively, thereby complicating the entire process. To solve such a problem, a dipping method is used to form the external electrode pairs 6 and 8 at the body 4. As illustrated in FIG. 2A, the dipping method includes dipping a side surface 4a of the body 4 and top and bottom surfaces 4b and 4c, respectively, of the body 4 into a liquid form conductive paste 10. Then, the conductive paste is thermally processed. At this time, the external electrode pairs 6 and 8 formed at the top and bottom surfaces 4c and 4b of the body 4 are thinner in thickness than those formed at the side surface 4a of the body 4, as illustrated in FIG. 2B. Moreover, the heights and surface areas of the external electrode pairs 6 and 8 formed at the bottom surface 4c of the body 4 are surface mounted on the LCD panel. However, the heights and surface areas of the external electrode pairs 6 and 8 formed at the bottom surface 4c are uneven. It is difficult to properly mount the chip type electric device having external electrode pairs with uneven heights on a lower substrate of the LCD panel. If the chip type electric device is mounted on the lower substrate using the external electrode pairs with the heights which are high, the external electrodes with the higher heights are connected to a signal pad formed on the lower substrate, but the lower heights of the external electrodes are not connected to the signal pad formed on the lower substrate. Furthermore, the chip type electric device 2 having external electrodes 6 and 8 with uneven surface areas that differ from the corresponding contact areas of the signal pad formed on the lower substrate results in a defective contact therebetween.

### BRIEF SUMMARY OF THE INVENTION

Therefore, an exemplary embodiment of the present invention provides a chip type electric device capable of preventing a bonding defect caused by a deviation in height between external electrodes, and a display device including the same.

In accordance with another exemplary embodiment of the present invention, a chip type electric device comprises a body in which a plurality of dielectric layers is stacked, a contact hole penetrating at least one of the plurality of dielectric layers, pairs of connection electrodes buried within the contact hole, and pairs of external electrodes connected to the pairs of connection electrodes and formed on a back surface of the body.

An exemplary embodiment of the chip type electric device further includes a resistance layer formed on a front surface of the body and connected to the pairs of external electrodes.

Another exemplary embodiment of the chip type electric device further includes pairs of internal electrodes alternately formed between the plurality of dielectric layers, the pairs of internal electrodes overlap each other with the dielectric layers disposed therebetween and are electrically connected to the pairs of external electrodes.

Another exemplary embodiment of the chip type electric device further includes an internal electrode formed in a spiral form on the plurality of dielectric layers and has one end and the other end connected to the pairs of external electrodes.

The chip type electric device further includes align marks formed at both outer sides of the back surface of the body.

The chip type electric device is at least one of a chip capacitor, a chip resistor, a chip inductor, a chip diode and a chip varistor.

In accordance with another exemplary embodiment of the present invention, a chip type electric device comprises a body in which a plurality of dielectric layers is stacked, a contact hole penetrating at least one of the plurality of dielectric layers, pairs of connection electrodes buried within the contact hole, and pairs of external electrodes connected to the pairs of connection electrodes, formed separately on a back surface of the body at given intervals, and connected to a signal pad of an insulation substrate through a conductive film.

The chip type electric device is at least one of a chip capacitor, a chip resistor, a chip inductor, a chip diode and a chip varistor.

The chip type electric device further includes align marks formed at both outer sides of the back surface of the body.

In accordance with still another exemplary embodiment of the present invention, a display device comprises a display panel in which a signal pad is formed, and a chip type electric device mounted on the display panel and connected to the signal pad. The chip type electric device includes a body in which a plurality of dielectric layers is stacked, a contact hole penetrating the plurality of dielectric layers, pairs of connection electrodes buried within the contact hole, and pairs of external electrodes connected to the pairs of connection electrodes, formed on a back surface of the body, and connected electrically to the signal pad.

The display device further includes a conductive film formed between the signal pad and the chip type electric device to connect the signal pad and the chip type electric device.

In accordance with yet another exemplary embodiment of the present invention, a method of forming a chip type electric device is disclosed. The method comprises stacking a plurality of dielectric layers to form a body and penetrating at least one of the plurality of dielectric layers to form a pair of contact holes. A pair of connection electrodes is buried each within a respective contact hole and a pair of external electrodes is connected to a respective connection electrode, the pair of external electrodes is formed on a back surface of the body.

### BRIEF DESCRIPTION OF THE DRAWINGS

The above and other aspects, features and advantages of the present invention will become more apparent from the following detailed description when taken in conjunction with the accompanying drawings in which:

FIG. 1 is a cross-sectional view of a conventional chip type electric device for mounting on a PCB;

FIGS. 2A and 2B are cross-sectional views of forming the external electrodes of the chip type electric device shown in FIG. 1;

FIG. 3 is a perspective view of a chip capacitor, as another exemplary embodiment of a chip type electric device, according to the present invention;

FIG. 4 is a cross-sectional view illustrating the chip capacitor shown in FIG. 3;

FIG. 5 is a cross-sectional view illustrating another exemplary embodiment of the chip capacitor shown in FIG. 3 according to the present invention;

FIG. 6 is a cross-sectional view of a chip resistor, as another exemplary embodiment of a chip type electric device, according to the present invention;

FIG. 7 is a cross-sectional view of a chip inductor, as another exemplary embodiment of a chip type electric device, according to the present invention;

FIG. 8 is a plane view of an LCD device having the chip type electric device shown in FIGS. 4, 6 and 7;

FIG. 9A is a cross-sectional view of a chip capacitor taken along line I-I′ shown in FIG. 8;

FIG. 9B is a cross-sectional view of a chip resistor taken along line II-II′ shown in FIG. 8; and

FIG. 9C is a cross-sectional view of a chip inductor taken along line III-III′ shown in FIG. 8.

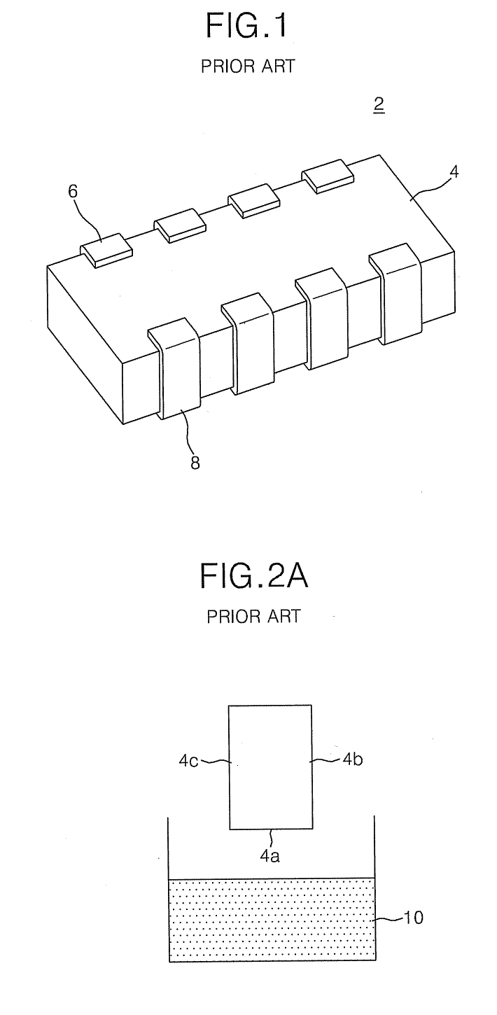

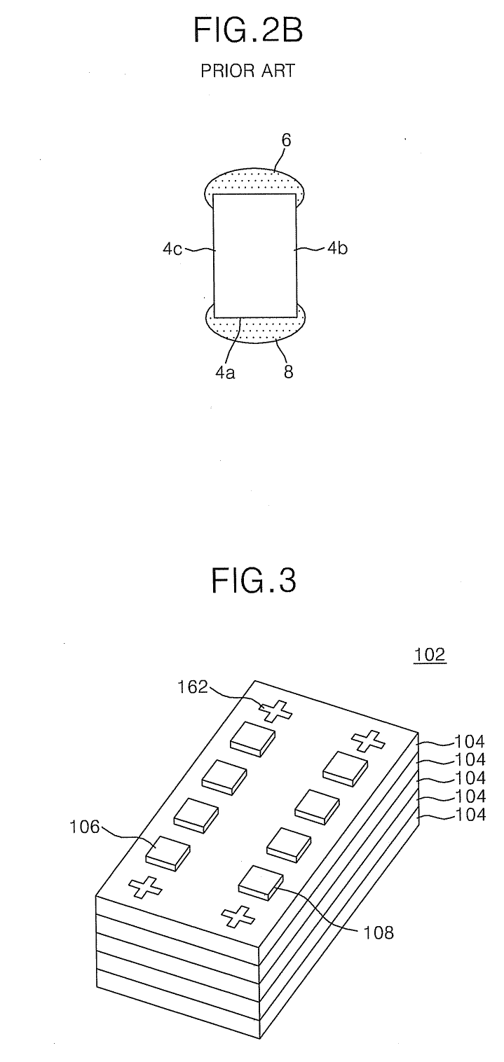

### DETAILED DESCRIPTION OF THE INVENTION

The exemplary embodiments of the present invention will now be described with reference to the attached drawings. The present invention may, however, be embodied in different forms and thus the present invention should not be construed as being limited to the exemplary embodiments set forth herein. Rather, these exemplary embodiments are provided so that this disclosure will be thorough and complete, and will fully convey the scope of the invention to those skilled in the art.

In the drawings, the thickness of the layers, films, and regions are exaggerated for clarity. When an element such as a layer, film, region, or substrate is referred to as being “on” another element, it can be directly on the other element or intervening elements may also be present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

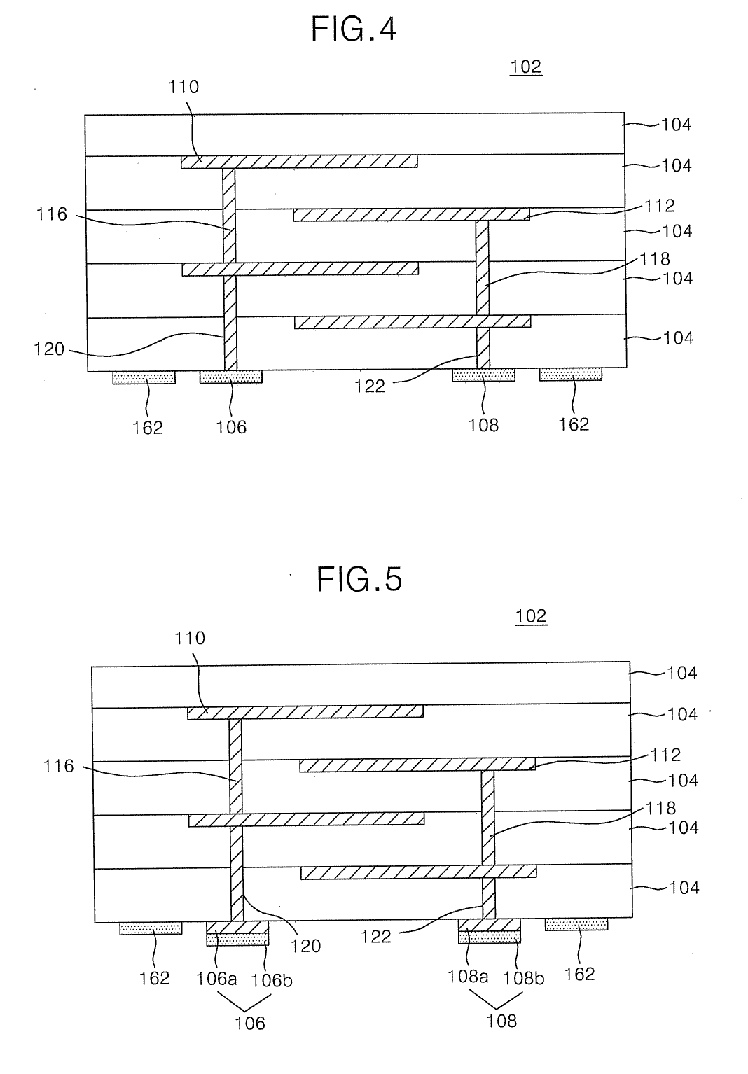

FIG. 3 is a perspective view of a chip capacitor, as an exemplary embodiment of a chip type electric device according to the present invention. FIG. 4 is a cross-sectional view illustrating the chip capacitor shown in FIG. 3.

Referring to FIGS. 3 and 4, a chip capacitor 102 includes a plurality of dielectric layers 104 (e.g., five shown), first and second internal electrodes 110 and 112, respectively, formed alternately between the plurality of dielectric layers 104, a first external electrode 106 connected to the first internal electrodes 110, a second external electrode 108 connected to the second internal electrodes 112, and align marks 162 formed at both or opposing outer sides of an outermost dielectric layer 104.

The plurality of dielectric layers 104 is formed in a multilayered structure made of a ceramic dielectric material and constitutes a body of the chip capacitor 102. The capacitance value of the capacitor 102 is determined according to a dielectric constant and thickness of the dielectric layers 104.

The first and second internal electrodes 110 and 112 face each other with the dielectric layers 104 disposed therebetween. The first and second internal electrodes 110 and 112 are formed of palladium (Pd), nickel (Ni), etc.

The first internal electrodes 110 are connected to each other through a first connection electrode 116 buried within a first contact hole 120 penetrating the dielectric layers 104. The first connection electrode 116 is formed of the same metal as the first internal electrodes 110 at the same time when the first internal electrodes 110 are formed. Alternatively, the first connection electrode 116 may be formed of a different metal from the first internal electrodes 110 by an additional process, or may be formed of the same metal as the first internal electrodes 110 by an additional process.

The second internal electrodes 112 are connected to each other through a second connection electrode 118 buried within a second contact hole 122 penetrating the dielectric layers 104. The second connection electrode 118 is formed of the same metal as the second internal electrodes 112 at the same time when the second internal electrodes 112 are formed. Alternatively, the second connection electrode 118 may be formed of a different metal from the second internal electrodes 112 by an additional process, or may be formed of the same metal as the second internal electrodes 112 by an additional process.

The first and second external electrodes 106 and 108 are formed of silver (Ag), copper (Cu), etc. and on the back of the outermost dielectric layer 104 by a photolithography process including an etching process or by a screen printing process.

As shown in FIG. 4, the first external electrode 106 is formed in a single layer structure on the outermost dielectric layer 104 so that it can be connected to the first internal electrodes 110 through the first connection electrode 116 buried within the first connect hole 120. Alternatively, the first external electrode 106 is formed, as shown in FIG. 5, in a multilayered structure on the outermost dielectric layer 104 so that it can be connected to the first internal electrodes 110 through the first connection electrode 116 buried within the first contact hole 120. For example, the first external electrode 106 formed in a multilayered structure includes a first electrode layer 106a formed of the same metal as the first connection electrode 116 on the outermost dielectric layer 104 and a second electrode layer 106b formed of the same metal as the align marks 162 on the first electrode layer 106a at the same time when the align marks 162 are formed.

The second external electrode 108 is formed, as shown in FIG. 4, in a single layer structure on the outermost dielectric layer 104 so that it can be connected to the second internal electrodes 112 through the second connection electrode 118 buried within the second connect hole 122. Alternatively, the second external electrode 108 is formed, as shown in FIG. 5, in a multilayered structure on the outermost dielectric layer 104 so that it can be connected to the second internal electrodes 112 through the second connection electrode 118 buried within the second contact hole 122. For example, the second external electrode 108 includes a first electrode layer 108a formed of the same metal as the second connection electrode 118 on the outermost dielectric layer 104 and a second electrode layer 108b formed of the same metal as the align marks 162 on the first electrode layer 108a at the same time when the align marks 162 are formed.

The align marks 162 are formed of the same metal as the external electrodes 106 and 108 on the same plane as the external electrodes 106 and 108. Alternatively, the align marks 162 are formed of the same metal as the internal electrodes 110 and 112 or the connection electrodes 116 and 118 on the same plane as at least one of the internal electrodes 110 and 112. The align marks 162 are used when the chip capacitor 102 is mounted on an LCD panel. The chip capacitor 102 is arranged on a lower substrate of the LCD panel such that the align marks 162 formed thereon can be aligned with those formed on the lower substrate of the LCD panel.

As described above, the internal electrodes 110 and 112 of the chip capacitor 102 are connected to the external electrodes 106 and 108 through the connection electrodes 116 and 122, respectively. Therefore, the external electrodes 106 and 108 of the chip capacitor 102 can be formed on the back of the outermost dielectric layer 104 by a photolithography process including a single etching process or by a screen printing process. The external electrodes 106 and 108 of the chip capacitor 102 according to the present invention can increase or improve flatness of the surfaces of the electrodes compared with the conventional external electrodes formed on the side and bottom of the body by a dipping method. Moreover, since the chip capacitor 102 according to the present invention includes the dielectric layers 104 of a multilayered structure, the surfaces of the dielectric layers 104 become flattened, and thus the flatness of the surfaces of the electrodes formed on the dielectric layers 104 can be improved. Accordingly, the inventive chip capacitor 102 can prevent a defective contact caused by a deviation in at least one of height and contact area between the external electrodes and the lower substrate of LCD panel, for example. Since align marks 162 are formed at both ends of the outermost dielectric layer 104, the chip capacitor 102 having the align marks 162 is accurately arranged on the LCD panel identically to an integrated circuit aligned by using additional align marks.

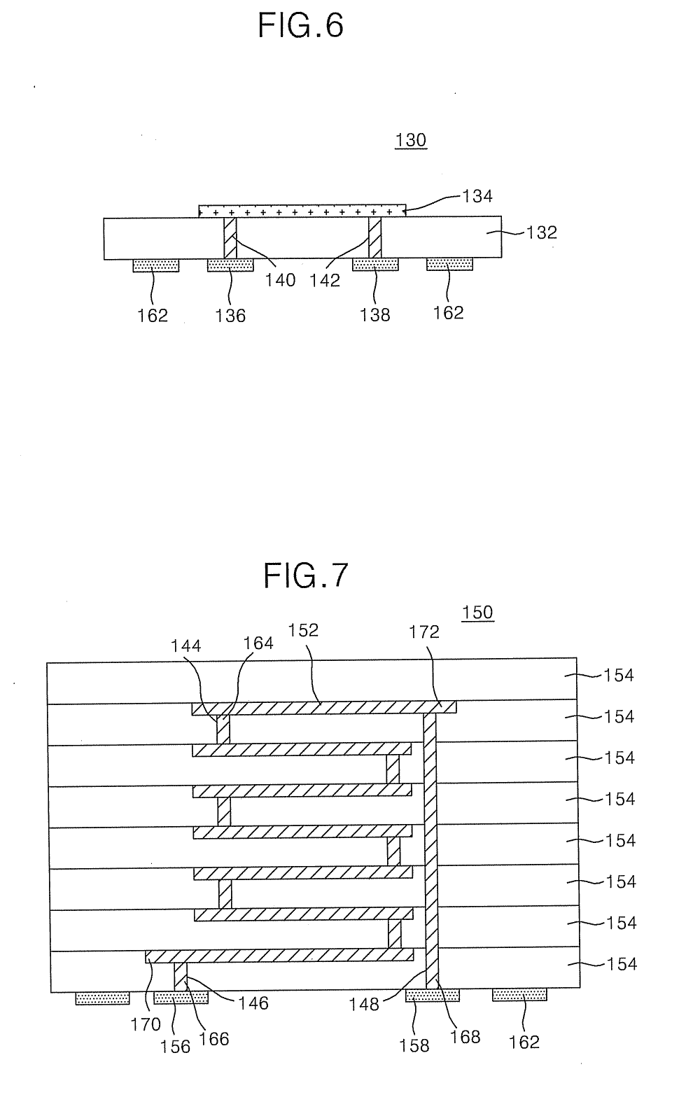

FIG. 6 is a cross-sectional view of a chip resistor, as another exemplary embodiment of a chip type electric device according to the present invention.

Referring to FIG. 6, a chip resistor 130 includes a resistance layer 134 formed on a front of a dielectric layer 132, which is a body, first and second external electrodes 136 and 138, respectively, connected to the resistance layer 134 and formed on a back of the dielectric layer 132, connection electrodes 140 formed between the first and second external electrodes 136 and 138, respectively, and the resistance layer 134, and align marks 162 formed at both outer sides of the back of the dielectric layer 132.

The resistance layer 134 is made of a resistance material such as oxide ruthenium (RuO₂) and determines the resistance value of the chip resistor 130.

The first and second external electrodes 136 and 138 are formed of metal such as Ag, Cu, Ni, etc. and formed on the back of the dielectric layers 132 in a single layer or multilayered structure by a photolithography process including an etching process or by a screen printing process. The first and second external electrodes 136 and 138 are connected to the resistance layer 134 through the connection electrodes 140 buried within respective contact holes 142.

The connection electrodes 140 are formed of the same metal as the first and second external electrodes 136 and 138 at the same time when the first and second external electrodes 136 and 138 are formed. Alternatively, the connection electrodes 140 may be formed of the same metal as the first and second external electrodes 136 and 138 by an additional process, or may be formed of a different metal from the first and second external electrodes 136 and 138 by an additional process.

The align marks 162 are formed of the same metal as the external electrodes 136 and 138 or the connection electrodes 140 and formed on the same plane as the external electrodes 136 and 138. The align marks 162 are used when the chip resistor 130 is mounted on the LCD panel. The chip resistor 130 is arranged on the lower substrate of the LCD panel such that the align marks 162 formed on the chip capacitor 130 can be aligned with those formed on the lower substrate of the LCD panel.

As described above, the internal electrodes of the chip resistor 130 are connected to the external electrodes 136 and 138 through the connection electrodes 140. Therefore, the external electrodes 136 and 138 of the chip resistor 130 can be formed on the back of the outermost dielectric layer 132 by a photolithography process including a single etching process or by a screen printing process. The external electrodes 136 and 138 of the chip resistor 130 according to the present invention can increase or improve flatness of the surfaces of the electrodes compared with the conventional external electrodes formed on the side and bottom of the body by a dipping method. Accordingly, the inventive chip resistor 130 can prevent defective contact caused by a deviation in at least one of height and contact area between the external electrodes 136 and 138 and the lower substrate of LCD panel, for example. Since align marks 162 are formed at both ends of the outermost dielectric layer 132, the chip resistor 130 having the align marks 162 is accurately arranged on the LCD panel identically to an integrated circuit aligned by using additional align marks.

FIG. 7 is a cross-sectional view of a chip inductor, as yet another exemplary embodiment of a chip type electric device, according to the present invention.

Referring to FIG. 7, a chip inductor 150 includes internal electrodes 152 formed in a spiral form on a plurality of dielectric layers 154, and external electrodes 156 and 158 connected to the internal electrodes 152.

The plurality of dielectric layers 154 is formed of a ceramic material in a multilayered structure and constitutes a body of the chip inductor 150.

The internal electrodes 152 are connected to each other through first connection electrodes 164 buried within respective first contact holes 144 penetrating the dielectric layers 154 and disposed between adjacent internal electrodes 152. The first connection electrodes 164 are formed of the same metal as the internal electrodes 152 at the same time when the internal electrodes 152 are formed. Alternatively, the first connection electrodes 164 may be formed of a different metal from the internal electrodes 152 by an additional process, or may be formed of the same metal as the internal electrodes 152 by an additional process. As illustrated in FIG. 7, the first connection electrodes 164 are alternately formed at the right and left of the internal electrodes 152 with the internal electrodes 152 disposed therebetween. Therefore, the internal electrodes 152 are formed in a spiral form through the first connection electrodes 164.

A first in/out portion 170, a start part of the internal electrodes 152 (e.g., one of the two outbound internal electrodes 152) of the spiral form, is connected to the first external electrode 156 through a second contact hole 146 penetrating the dielectric layers 154. In more detail, the first in/out portion 170 is connected to the first external electrode 156 through a second connection electrode 166 buried within the second contact hole 146.

A second in/out portion 172 (e.g., the other of the two outbound internal electrodes 152), an end part of the internal electrodes 152 of the spiral form, is connected to the second external electrode 158 through a third contact hole 148 penetrating the dielectric layers 154. In more detail, the second in/out portion 172 is connected to the second external electrode 158 through a third connection electrode 168 buried within the third contact hole 148.

The first and second external electrodes 156 and 158 are formed of metal such as Ag, Cu, etc. and formed on the outermost dielectric layer 154 in a single layer or multilayered structure by a photolithography process including an etching process or by a screen printing process.

Align marks 162 are formed of the same metal as the external electrodes 156 and 158 and formed on the same plane as the external electrodes 156 and 158. Alternatively, the align marks 162 may be formed of the same metal as the internal electrodes 152 or the connections electrodes 164, 166 and 168 and formed on the same plane as at least one of the internal electrodes 152. The align marks 162 are used when the chip inductor 150 is mounted on the LCD panel. The chip inductor 150 is arranged on the lower substrate of the LCD panel such that the align marks 162 formed on the chip inductor 150 can be aligned with those formed on the lower substrate of the LCD panel.

As described above, the internal electrodes 152 of the chip inductor 150 are connected to the external electrodes 156 and 158 through the connection electrodes 166 and 168, respectively. Therefore, the external electrodes 156 and 158 of the chip inductor 150 can be formed on the back of the outermost dielectric layer 154 by a photolithography process including a single etching process or by a screen printing process. The external electrodes 156 and 158 of the chip inductor 150 according to the present invention can increase or improve flatness of the surfaces of the electrodes compared with the conventional external electrodes formed on the side and bottom of the body by a dipping method. Moreover, since the chip inductor 150 according to the present invention includes the dielectric layers 154 of a multilayered structure, the surfaces of the dielectric layers 154 become flattened, and thus the flatness of the surfaces of the electrodes 156 and 158 formed on the dielectric layers 154 can be improved. Accordingly, the inventive chip inductor 150 can prevent defective contact caused by a deviation in at least one of height and contact area between the external electrodes and the lower substrate of LCD panel, for example. Since align marks 162 are formed at both ends of the outermost dielectric layer 154, the chip inductor 150 having the align marks 162 is accurately arranged on the LCD panel identically to an integrated circuit aligned by using additional align marks.

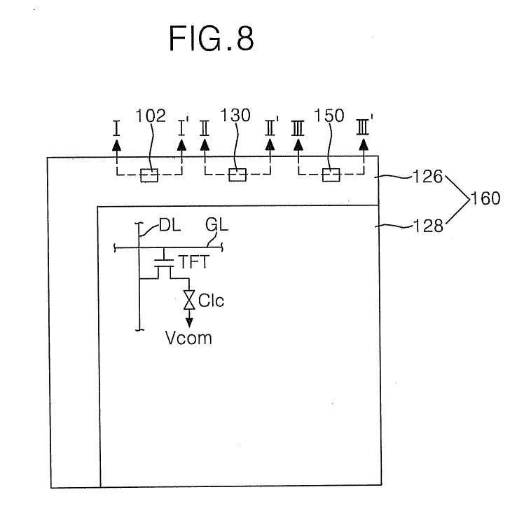

FIG. 8 illustrates an LCD device on which the chip type electric device of the present invention is mounted.

Referring to FIG. 8, an LCD device on which the chip type electric device of the present invention is mounted includes a thin film transistor (“TFT”) 126 and a color filter substrate 128 that face each other with a liquid crystal material (not shown) disposed therebetween and that are assembled together.

The color filter substrate 128 includes a black matrix for preventing light leakage, a color filter for achieving colors, a common electrode for forming a vertical electric field with a pixel electrode, and an upper alignment layer coated for the alignment of liquid crystals, all of which are formed on an upper substrate.

The TFT substrate 126 includes a gate line GL and a data line DL formed to cross each other, a TFT formed at an intersection of the data line GL and the data line DL, a pixel electrode that is connected to the TFT and faces a common electrode with liquid crystals disposed therebetween and forms a liquid crystal cell Clc, and a lower alignment layer coated for the alignment of liquid crystals, all of which are formed on a lower substrate.

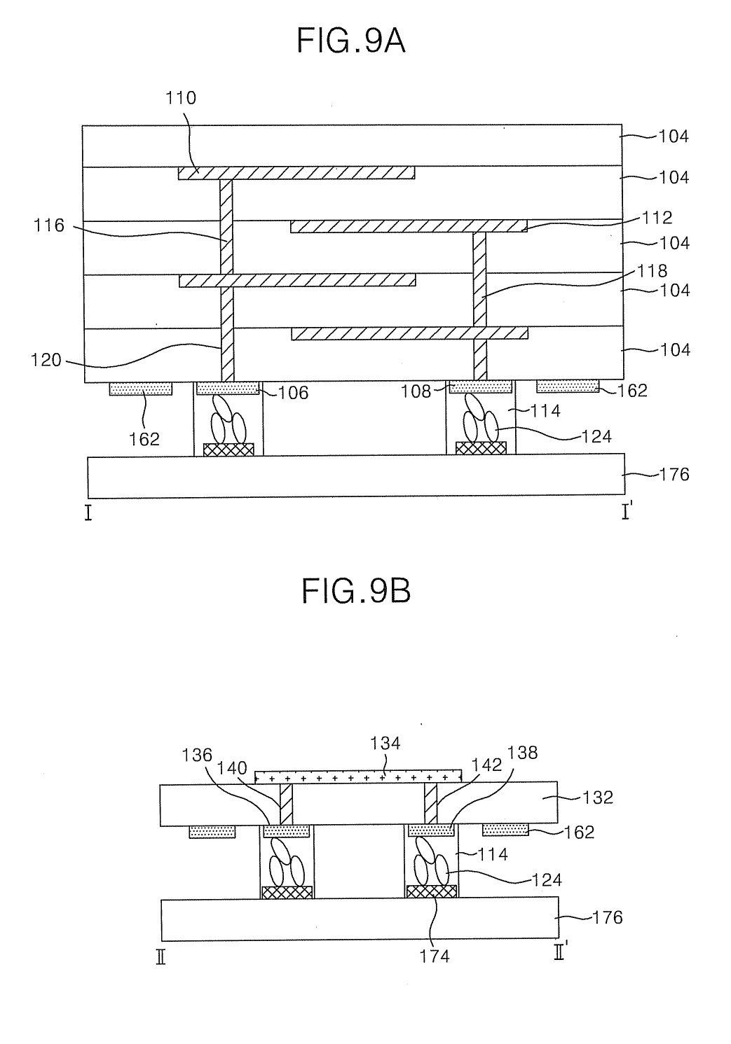

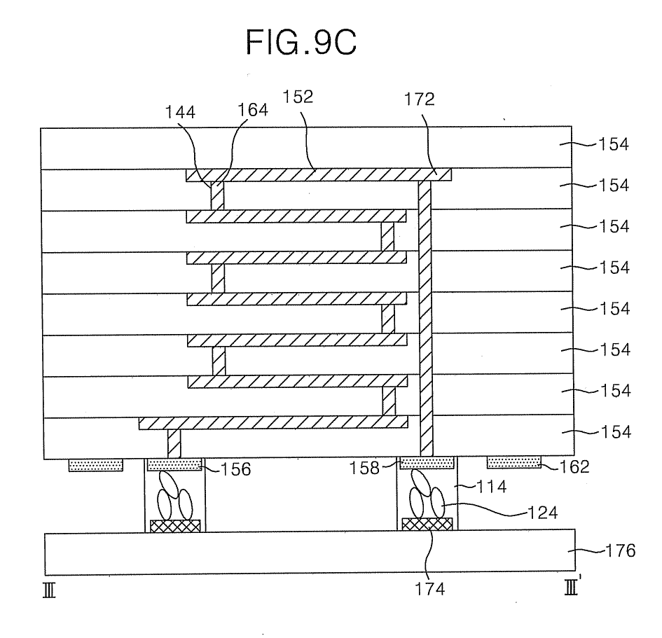

At least one chip type electric device among the multilayer ceramic capacitor 102 shown in FIGS. 4 and 5, the chip resistor 130 in FIG. 6 and the chip inductor 150 in FIG. 7 is mounted on the lower substrate of the TFT substrate 126. As shown in FIGS. 9A to 9C, the external electrodes 106, 108, 136, 138, 156 and 158 of these chip type electric devices are connected to signal pads 174 formed on a lower substrate 176 through anisotropic conductive films (“ACFs”) 114 having conductive balls 124.

While the chip resistor 130, chip capacitor 102 and chip inductor 150 have been described as examples of the chip type electric device, it is possible that the chip type electric device is also applied to a chip diode, a chip varistor, etc.

Moreover, while the chip type electric device has been described as being mounted on the lower substrate 176 by using the ACF 114, it may be mounted on a PCB and an FPC by using the ACF 114. The chip type electric device may also be mounted on at least one of the lower substrate 176, a PCB and an FPC by a soldering process.

The chip type electric device is applicable to a plasma display panel, a field emission device, an electro-luminescent device, etc., in addition to an LCD device.

As can be appreciated from the foregoing description, the chip type electric device and the display device including the same form first and second external electrodes on the back of the outermost dielectric layer and form align marks at both ends of the outermost dielectric layer. Therefore, a defective contact caused by a deviation in height between the first and second external electrodes can be prevented. Furthermore, the chip type electric device can be arranged at an accurate position of the display panel by using the align marks.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A chip type electric device, comprising:
a body in which a plurality of dielectric layers is stacked;
a pair of contact holes each penetrating at least one of the plurality of dielectric layers;
a pair of connection electrodes each buried within a respective contact hole; and
a pair of external electrodes each connected to a respective connection electrode and formed on a back surface of the body.

2. The chip type electric device of claim 1, further comprising a resistance layer formed on a front surface of the body and connected to the pair of external electrodes.

3. The chip type electric device of claim 1, further comprising pairs of internal electrodes that are alternately formed between the plurality of dielectric layers, the pairs of internal electrodes overlap each other with the dielectric layers disposed therebetween and are electrically connected to the pair of external electrodes.

4. The chip type electric device of claim 1, further comprising an internal electrode that is formed in a spiral form on the plurality of dielectric layers and has one end and the other end connected to the pair of external electrodes.

5. The chip type electric device of claim 1, further comprising align marks formed at both outer sides of the back surface of the body.

6. The chip type electric device of claim 1, wherein the chip type electric device is at least one of a chip capacitor, a chip resistor, a chip inductor, a chip diode and a chip varistor.

7. A chip type electric device, comprising:
a body in which a plurality of dielectric layers is stacked;
a pair of contact holes each penetrating at least one of the plurality of dielectric layers;
a pair of connection electrodes each buried within a respective contact hole; and
a pair of external electrodes each connected to a respective connection electrode, each external electrode formed separately on a back surface of the body at given intervals, and connected to a signal pad of an insulation substrate through a conductive film.

8. The chip type electric device of claim 7, wherein the chip type electric device is at least one of a chip capacitor, a chip resistor, a chip inductor, a chip diode and a chip varistor.

9. The chip type electric device of claim 7, further comprising align marks formed at both outer sides of the back surface of the body.

10. A display device, comprising:
a display panel in which a signal pad is formed; and
a chip type electric device mounted on the display panel and connected to the signal pad;
wherein the chip type electric device comprises;
a body in which a plurality of dielectric layers is stacked,
a pair of contact holes each penetrating the plurality of dielectric layers,
a pair of connection electrodes each buried within a respective contact hole, and
a pair of external electrodes each connected to a respective connection electrode, each external electrode formed on a back surface of the body, and connected electrically to the signal pad.

11. The display device of claim 10, further comprising a conductive film formed between the signal pad and the chip type electric device to connect the signal pad and the chip type electric device.

12. The display device of claim 10, further comprising a resistance layer formed on a front surface of the body and connected to the pair of external electrodes.

13. The display device of claim 10, further comprising pairs of internal electrodes that are alternately formed between the plurality of dielectric layers, the pairs of internal electrodes overlap each other with the dielectric layers disposed therebetween and are electrically connected to the pair of external electrodes.

14. The display device of claim 10, further comprising an internal electrode that is formed in a spiral form on the plurality of dielectric layers and has one end and the other end connected to the pair of external electrodes.

15. The display device of claim 10, further comprising align marks formed at both outer sides of the back surface of the body.

16. The display device of claim 10, wherein the chip type electric device is at least one of a chip capacitor, a chip resistor, a chip inductor, a chip diode and a chip varistor.

17. A method of forming a chip type electric device, the method comprising:
stacking a plurality of dielectric layers to form a body;
penetrating at least one of the plurality of dielectric layers to form a pair of contact holes;
burying a pair of connection electrodes each within a respective contact hole; and
connecting a pair of external electrodes to a respective connection electrode, the pair of external electrodes formed on a back surface of the body.

18. The method of claim 17, further comprising forming a resistance layer on a front surface of the body and connected to the pair of external electrodes.

19. The method of claim 17, further comprising alternately forming pairs of internal electrodes between the plurality of dielectric layers, the pairs of internal electrodes overlap each other with the dielectric layers disposed therebetween and are electrically connected to the pair of external electrodes.

20. The method of claim 17, further comprising forming an internal electrode in a spiral form on the plurality of dielectric layers, the internal electrode having one end and the other end connected to the pair of external electrodes.

21. The method of claim 17, further comprising forming align marks at both outer sides of the back surface of the body.

22. The method of claim 17, wherein the chip type electric device is at least one of a chip capacitor, a chip resistor, a chip inductor, a chip diode and a chip varistor.
